(19) United States
(12) Patent Application Publication
(10) Pub. No.: US 2008/0225473 A1
(43) Pub. Date: Sep. 18, 2008

(54) PLASMA DISPLAY MODULE AND METHOD OF ADHERING AND SEPARATING PLASMA DISPLAY PANEL TO AND FROM CHASSIS

(75) Inventor: Hyuk Kim, Suwon (KR)

Correspondence Address: KNOBBE MARTENS OLSON & BEAR LLP, 2040 MAIN STREET, FOURTEENTH FLOOR, IRVINE, CA, 92614, US

(73) Assignee: Samsung SDI Co., Ltd, Suwon (KR)

(21) Appl. No.: 12/124,964

(22) Filed: May 21, 2008

Related U.S. Application Data
(63) Continuation of application No. 11/724,734, filed on Mar. 15, 2007.

(30) Foreign Application Priority Data
Jun. 20, 2006 (KR) 10-2006-0055409

(51) Int. Cl. H05K 7/14; G06F 1/16

(52) U.S. Cl. 361/681

(57) ABSTRACT

A plasma display module in which a chassis can be readily and quickly separated from a plasma display panel, and methods of attaching and detaching the plasma display panel to and from the chassis are disclosed. In one embodiment, the plasma display module includes a chassis that is disposed on an opposite side of the plasma display panel where an image is displayed and supports the plasma display panel, plates coupled to a surface of the chassis facing the plasma display panel, and a double-sided tape, wherein a surface of the double-sided tape is attached to a surface of the plasma display panel facing the chassis and the other surface of the double-sided tape is attached to each of the plates.

### CROSS-REFERENCE TO RELATED PATENT APPLICATION

This application is a continuation application which claims priority under 35 U.S.C. §120 from application No. 11/724,734 filed Mar. 15, 2007, which is hereby incorporated by reference. Application No. 11/724,734 claimed the benefit of Korean Patent Application No. 10-2006-0055409, filed on Jun. 20, 2006, in the Korean Intellectual Property Office, the disclosure of which is incorporated herein in its entirety by reference.

### BACKGROUND OF THE INVENTION

1. Field of the Invention

The present invention relates to a plasma display module and a method of adhering the plasma display panel to a chassis and separating the plasma display panel from the chassis. More particularly, the invention relates to a plasma display module in which a chassis can be readily and quickly separated from a plasma display panel when the chassis is required to be separated from the plasma display panel in order to repair the plasma display module after the plasma display module has been manufactured, and a method of adhering the plasma display panel to the chassis and separating the plasma display panel from the chassis

2. Description of the Related Technology

A plasma display module is a flat panel display device that displays an image using a gas discharge. Recently, the plasma display module has received much attention as a large flat panel display apparatus since it can be manufactured to be large, thin sized, having a wide viewing angle, and can display high quality images. The plasma display module includes a plasma display panel that displays images using a gas discharge and a chassis that supports the plasma display panel. A circuit substrate that drives the plasma display panel is coupled on a rear surface of the chassis. The circuit substrate and electrodes of the plasma display panel are electrically connected to each other by a signal transmitting element such as a tape carrier package (TCP) or a flexible printed circuit (FPC).

To inspect the quality of the TCP or FPC where integrated circuits are integrated, the plasma display module in which a chassis and a plasma display panel are coupled is tested. In this process, when a failure is detected in the TCP or FPC, the chassis and the plasma display panel are separated in order to repair the TCP or FPC.

FIG. 1 is a schematic cross-sectional view illustrating a conventional method of separating a plasma display panel 1 and a chassis 2 in a plasma display module. Referring to FIG. 1, in the conventional method of separating the plasma display panel 1 from the chassis 2, the plasma display module is disposed so that the plasma display panel 1 is disposed on an upper side, and the plasma display module is heated to maximum of about 480° C. for approximately 12 to 15 minutes from a lower side of the chassis 2 using a heating lamp 5. Afterwards, when the adhesion force of a double-sided tape 3 is reduced, a suction device 4 lifts the plasma display panel 1 by suction.

The conventional separation method is time consuming and odorous due to heating. Also, in some cases, the plasma display panel 1 is damaged by the heat or the chassis 2 must be discarded.

### SUMMARY OF CERTAIN INVENTIVE ASPECTS

One aspect of the present invention provides a plasma display module in which a plasma display panel can be readily and quickly separated from a chassis, and a method of attaching and separating the plasma display panel to and from the chassis.

Another aspect of the present invention provides a plasma display module comprising, i) a plasma display panel that displays an image using a gas discharge, ii) a chassis that is disposed on an opposite side of the plasma display panel where an image is displayed and supports the plasma display panel, iii) plates coupled to a surface of the chassis facing the plasma display panel and iv) a double-sided tape, wherein a surface of the double-sided tape is attached to a surface of the plasma display panel facing the chassis and the other surface of the double-sided tape is attached to each of the plates.

The coupling between the chassis and the plates may be tox joining in which a portion of and overlapping part of the chassis and the plate protrudes away from the plasma display panel from the chassis.

Another aspect of the present invention provides a method of attaching a plasma display panel and a chassis comprising: i) coupling plates on a surface of the chassis that faces the plasma display panel and supports the plasma display panel where an image is displayed, ii) attaching one of the surfaces of double-sided tapes to a portion of a surface of the plasma display panel facing the chassis corresponding to the plates and iii) attaching the other surfaces of the double-sided tapes to the plates.

Still another aspect of the present invention provides a method of separating a plasma display panel from a chassis comprising: i) removing a coupling part of a chassis of the plasma display module of the above plasma display module and plates, ii) separating the chassis from the plasma display module and iii) separating double-sided tapes from the plasma display panel.

The removing of the coupling part may be achieved by cutting the coupling part protruding away from the plasma display panel from the surface of the chassis at an overlapping part of the chassis and the plates.

The chassis may be readily separated from the plasma display panel since, as long as the tox joining is removed from the plasma display module, the coupling between the chassis and the plasma display panel is released. Accordingly, when there is a failure in the plasma display module, the failure can be readily repaired. Also, the damage of the plasma display panel can be prevented since heat is not used, and the chassis can be reused.

### BRIEF DESCRIPTION OF THE DRAWINGS

Embodiments of the present invention will be described with reference to the attached drawings.

FIG. 1 is a schematic cross-sectional view illustrating a conventional method of separating a plasma display panel and a chassis in a plasma display module.

FIG. 2 is an exploded perspective view illustrating a plasma display module according to an embodiment of the present invention.

FIG. 3 is a cross-sectional view illustrating a method of coupling a chassis and a plate in the plasma display module illustrated in FIG. 2, according to an embodiment of the present invention.

FIG. 4 is a side cross-sectional view taken along line IV-IV of the plasma display module illustrated in FIG. 2, according to an embodiment of the present invention.

FIG. 5 is a flow chart illustrating a method of attaching a plasma display panel and a chassis according to an embodiment of the present invention.

FIG. 6 is a flow chart illustrating a method of separating a plasma display panel from a chassis according to an embodiment of the present invention.

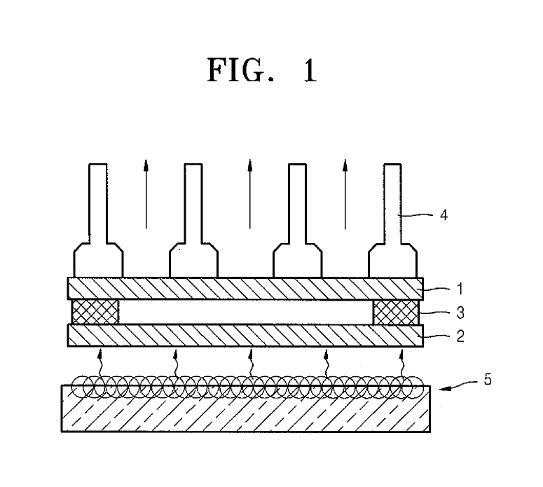

### DETAILED DESCRIPTION OF CERTAIN INVENTIVE EMBODIMENTS

Embodiments of the present invention will now be described more fully with reference to the accompanying drawings in which exemplary embodiments of the invention are shown.

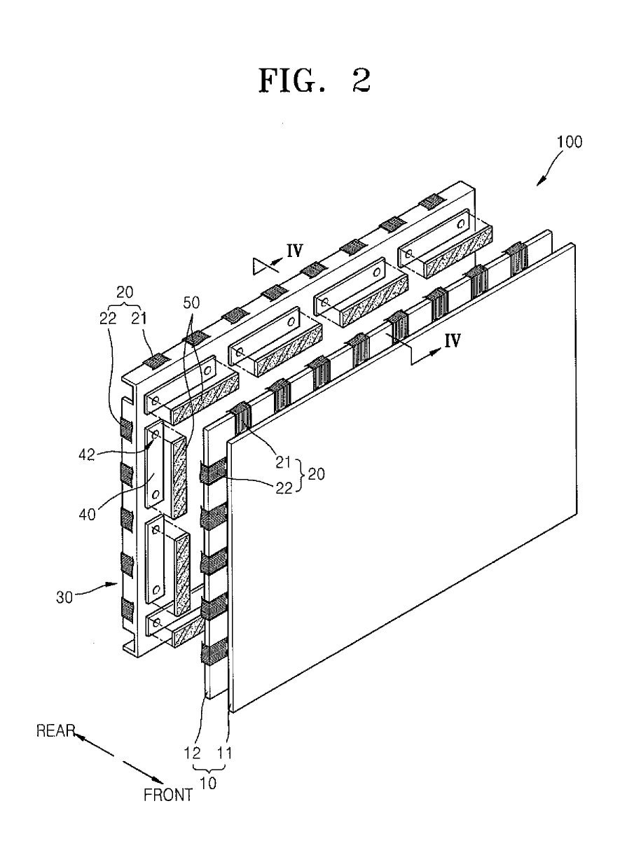

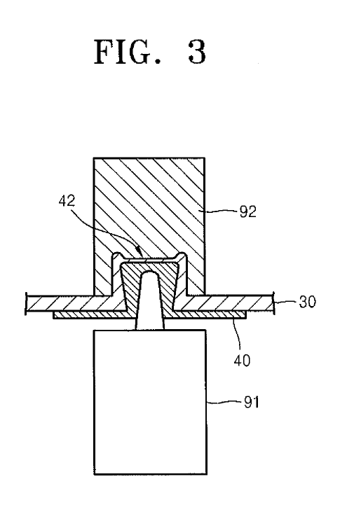

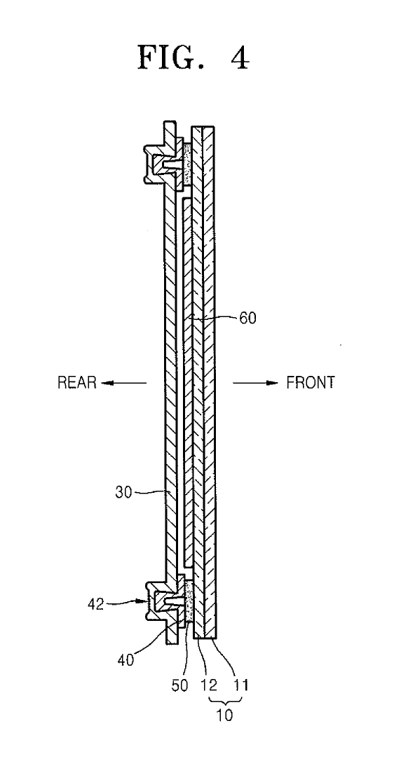

FIG. 2 is an exploded perspective view illustrating a plasma display module 100 according to an embodiment of the present invention. FIG. 3 is a cross-sectional view illustrating a method of coupling a chassis and a plate in the plasma display module 100 illustrated in FIG. 2, according to an embodiment of the present invention, and FIG. 4 is a side cross-sectional view taken along line IV-IV of the plasma display module 100 illustrated in FIG. 2, according to an embodiment of the present invention.

The plasma display module 100 includes a plasma display panel 10, a chassis 30, a plurality of plates 40, a plurality of double-sided tapes 50, a heat dissipation sheet 60 (refer to FIG. 4), a circuit substrate (not shown), and signal transmitting elements 20 (for example, elements 21 and 22).

The plasma display panel 10 is made by coupling a front panel 11 and a rear panel 12. Although it is not shown, if the plasma display panel 10 is of an alternate current three electrodes surface discharge type, the front panel 11 includes a front substrate, a plurality of sustain electrode pairs, a first dielectric layer, and a protective layer, and the rear panel 12 includes a rear substrate, a plurality of address electrodes, a second dielectric layer, a phosphor layer, and a barrier rib. Also, the plasma display panel 10 can be a panel that includes two electrodes, a direct current type of plasma display panel 10, or a facing discharge type of plasma display panel 10. When a predetermined pulse voltage is applied to the electrodes of the plasma display panel 10, a discharge is generated in each discharge cell, and thus, ultraviolet rays are generated from the discharges. The ultraviolet rays excite the phosphor layer of the plasma display panel 10 to emit visible light that forms an image.

In this way, the plasma display panel 10 is coupled to the chassis 30, and usually double-sided tapes 50 are used to directly couple the plasma display panel 10 to the chassis 30. However, in one embodiment, unlike in the prior art, the double-sided tapes 50 do not directly couple the plasma display panel 10 and the chassis 30. More specifically, the plates 40 may be coupled along upper, lower, left side, and right side edges of a front surface of the chassis 30. In one embodiment, the locations for the plates 40 are formed corresponding to the locations where the double-sided tapes 50 are attached to the chassis 30. In one embodiment, a rear surface of the chassis 30 and a coupling part 42 of the plate 40 are formed by, for example, a tox joining method. In one embodiment, to perform the method of tox joining, the chassis 30 is formed of a metal such as Al or electrolytic galvanized iron (EGI). In another embodiment, other joining methods can be used as long as they can provide strong attachment and easy separation.

The tox joining is a method of binding the chassis 30 and the plate 40 by protruding a portion of an overlapping part of the chassis 30 and the plate 40 away from the rear surface of the chassis 30. The method of tox joining will be described with reference to FIG. 3. A die 92 having a concave shape is disposed on a side of the chassis 30 where the chassis 30 overlaps the plate 40, and a punch 91 having a protruding shape is disposed in a side of the plate 40 to correspond to the concave shape of the die 92. Afterwards, a pressure is applied with respect to the die 92 using the punch 91.

As a result, a portion of the overlapping part of the chassis 30 and the plate 40 pushed by the punch 91 protrudes in the same shape as the concave shape of the die 92, and thus, the coupling part 42 as depicted in FIG. 4 is formed. Accordingly, as depicted in FIG. 4, coupling forces in directions towards the front, rear, up, and down are generated between the chassis 30 and the plate 40. In one embodiment, in the method of tox joining, the plate 40 is formed of a metal, and particularly, the metal may be Al. In one embodiment, the plate 40 and the chassis 30 are designed to suitable thicknesses for the method of tox joining.

The number of plates and the positions of the plates 40 may vary according to specifications. For example, the plates 40 may or may not be disposed on the left and right sides of the chassis 30. Also, the number of tox joinings in each plate 40 may vary.

In one embodiment, the double-sided tapes 50 are disposed in locations corresponding to the plates 40, and the size of the plates 40 may be greater than the size of the double-sided tapes 50 in order to prevent the chassis 30 from directly contacting the double-sided tapes 50. A surface of the double-sided tapes 50 contacts the plates 40, and the other surface of the double-sided tape 50 contacts a rear surface of the plasma display panel 10. To dissipate heat generated from the plasma display panel 10, a heat dissipation sheet 60 can be coupled to the rear surface of the plasma display panel 10.

Circuit substrates (not shown) are coupled to the rear surface of the chassis 30. The circuit substrates can include a power source board, a logic board, an address electrode driving board, an X electrode driving board, and a Y electrode driving board. The address electrode driving board, the X electrode driving board, and the Y electrode driving board generate pulse voltages applied to the address electrodes, an X electrode, and a Y electrode of the plasma display panel 10. The pulse voltages are applied to each of the electrodes by the signal transmitting elements 20 such as a TCP or a FPC. In one embodiment, the signal transmitting elements 20 are included in the plasma display panel 10 in a connected state to an electrode terminal unit of the plasma display panel 10.

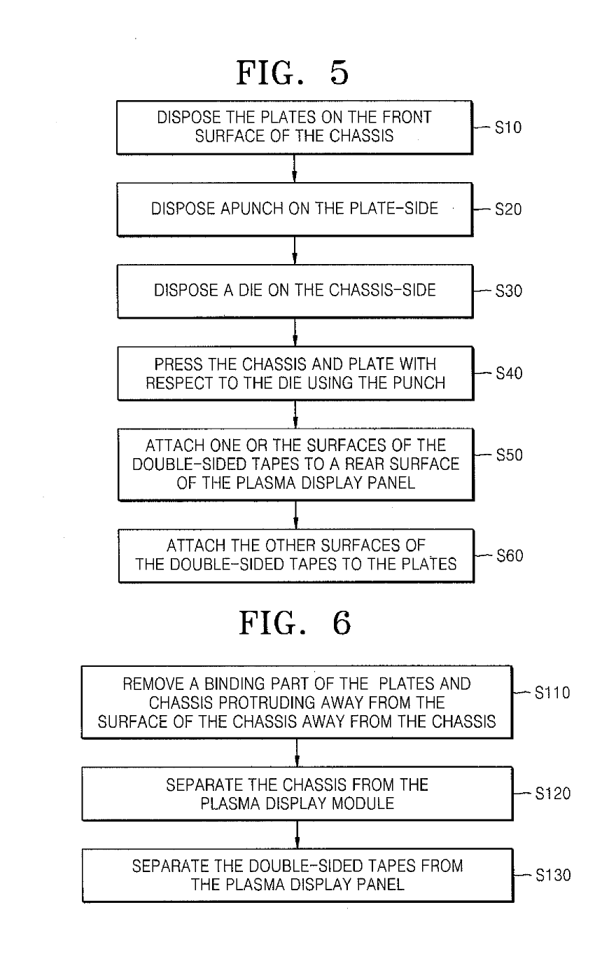

FIG. 5 is a flow chart illustrating a method of attaching the plasma display panel 10 and the chassis 30 according to an embodiment of the present invention. Depending on the embodiment, additional steps may be added, others removed, or the orders of the states may be changed in FIG. 5. Referring to FIG. 5, the method of attaching the plasma display panel 10 to the chassis 30 will now be described. The plate 40 is coupled to a front surface of the chassis 30 facing the plasma display panel 10. More specifically, after each of the plates 40 is disposed on the front surface of the chassis 30 (S10), the punch 91 is disposed on a side of the plate 40 (S20), and the die 92 is disposed on a side of the chassis 30 (S30). When the plate 40 and the chassis 30 are pressed with respect to the die 92 using the punch 91, the plate 40 and the chassis 30 are tox coupled (S40).

One of the surfaces of the double-sided tapes 50 is attached to a portion of the rear surface of the plasma display panel 10 facing the chassis 30 corresponding to the plate 40 (S50). Afterward, the other surface of the double-sided tape 50 is attached to a surface of the plate 40 connected to the chassis 30 (S60). In this way, the plasma display panel 10 and the chassis 30 are coupled, and the signal transmitting elements 20 are connected to the circuit substrates of the chassis 30, thus, the manufacture of the plasma display module 100 is complete.

However, a failure may occur in the TCP since integrated circuits (ICs), for example, address electrode driving chips are integrated. In one embodiment, when a failure is detected in the TCP or FPC in an inspection process of the plasma display module 100, the failure in the plasma display module 100 can be repaired by separating the chassis 30 from the plasma display module 100.

FIG. 6 is a flow chart of a method of separating the plasma display panel 10 from the chassis 30 according to an embodiment of the present invention. Depending on the embodiment, additional steps may be added, others removed, or the orders of the states may be changed in FIG. 6. Hereinafter, the method of separating the chassis 30 from the plasma display module 100 will now be described with reference to FIG. 6. The coupling part 42 where the chassis 30 and the plate 40 are tox joined is removed from the plasma display module 100 depicted in FIGS. 2 and 3 (S110). The removal of the coupling part 42 can be achieved by cutting the coupling part 42 protruded away from the surface of the chassis 30 at an overlapping part of the chassis 30 and the plate 40 using a tox remover (not shown). In one embodiment, other removing methods are also possible as long as they can easily separate the coupling part 42 from the chassis 30 without significantly damaging the plasma display panel 10 and/or the chassis 30. In the method of tox joining, as depicted in FIG. 3, the coupling forces towards the front, rear, up, and down are generated by the coupling part 42. Therefore, when the coupling part 42 is removed, the coupling force between the chassis 30 and the plate 40 is removed. Accordingly, the chassis 30 can be readily separated from the plasma display module 100 (S120).

Afterwards, the plates 40 and the double-sided tapes 50 are separated from the plasma display panel 10 (S130). To remove the double-sided tapes 50 from the plasma display panel 10, an end of each of the double-sided tapes 50 is detached from the plasma display panel 10 in a direction toward the other end of the double-sided tapes 50 since the double-sided tapes 50 have high shear stress and high tensile strength.

In this way, since heat is not used to separate the chassis 30 from the plasma display module 100, the removal time can be reduced and damages to the plasma display panel 10 can be avoided. Also, the chassis 30 can be reused without being discarded.

In a plasma display module according to one embodiment of the present invention, a chassis can be readily separated from the plasma display module by removing a tox joined binding part without significantly damaging the plasma display panel and/or the chassis. Accordingly, a failure of the plasma display module can be rapidly repaired, damages of the plasma display panel due to heat can be prevented, and the removed chassis can be reused.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A plasma display module comprising:
a plasma display panel that displays an image using a gas discharge;
a chassis disposed on a side of the plasma display panel opposite to a side where an image is displayed, having a first surface facing the plasma display panel and second surfaces opposite to the first surface, and supporting the plasma display panel;
a plurality of plates comprising coupling parts to the first surface of the chassis; and
a plurality of double-sided tapes, wherein one surface of each of the double-sided tapes is attached to a surface of the plasma display panel facing the chassis and the other surface of each of the double-sided tapes is attached to each of the plates.

2. The plasma display module of claim 1, wherein the plates are formed of a material containing aluminum.

3. The plasma display module of claim 1, wherein the plates are formed along at least edges of the surface of the chassis.

4. The plasma display module of claim 1, wherein the coupling part of the plate comprises a protrusion part which protrudes away from the first surface to the second surface of the chassis.

5. The plasma display module of claim 4, wherein the chassis comprises a protrusion part which corresponds to the protrusion part of the plate and protrudes away from the first surface to the second surface of the chassis,

6. A method of attaching a plasma display panel and a chassis comprising:
coupling a plurality of plates on a surface of the chassis that faces the plasma display panel and supports the plasma display panel where an image is displayed;
attaching one surface of each of a plurality of double-sided tapes to a portion of a surface of the plasma display panel facing the chassis corresponding to the plates; and
attaching the other opposing surface of each of the double-sided tapes to the plates.

7. The method of claim 6, wherein the plates are coupled to the chassis along edges of the surface of the chassis.

8. The method of claim 6, wherein the plates are formed of a material containing aluminum.

9. The method of claim 6, wherein the coupling comprises:
disposing the plates on the surface of the chassis facing the plasma display panel;
disposing a punch having a protrusion on the plate-side of an overlapping part of the chassis and each plate;
disposing a die having a concave shape on the chassis-side of the overlapping part of the chassis and plates; and
pressing the plates and the chassis toward the die by way of the punch.

10. A method of separating a plasma display panel from a chassis comprising:
removing coupling parts of a chassis of a plasma display module and plates, wherein the plasma display module comprises i) a plasma display panel that displays an image using a gas discharge, ii) a chassis disposed on a side of the plasma display panel opposite to a side where an image is displayed, having a first surface facing the plasma display panel and second surfaces opposite to the first surface, and supporting the plasma display panel, iii) a plurality of plates comprising coupling parts to the first surface of the chassis and iv) a plurality of double-sided tapes, wherein one surface of each of the double-sided tapes is attached to a surface of the plasma display panel facing the chassis and the other surface of each of the double-sided tapes is attached to each of the plates;
separating the chassis from the plasma display module; and
separating each of double-sided tapes from the plasma display panel.

11. The method of claim 10, wherein the removing is achieved by cutting the coupling part protruding away from the surface of the chassis at an overlapping part of the chassis and the plates.

12. The method of claim 10, wherein the separating is achieved by detaching an end of each of the double-sided tapes in a direction toward the other end of each of the double-sided tapes.
